(19) United States
(12) Patent Application Publication
(10) Pub. No.: US 2013/0334635 A1
(43) Pub. Date: Dec. 19, 2013

(54) PIXEL STRUCTURE WITH REDUCED VACUUM REQUIREMENTS

(71) Applicant: RAYTHEON COMPANY, Waltham, MA (US)

(72) Inventors: Adam M. Kennedy, Santa Barbara, CA (US); Stephen H. Black, Buellton, CA (US)

(73) Assignee: RAYTHEON COMPANY, Waltham, MA (US)

(21) Appl. No.: 13/628,248

(22) Filed: Sep. 27, 2012

Related U.S. Application Data
(60) Provisional application No. 61/660,068, filed on Jun. 15, 2012.

(51) Int. Cl. H01L 31/02

(52) U.S. Cl. 257/431; 257/E31.11

(57) ABSTRACT

A pixel structure, which may be used for infrared bolometers or other microelectromechanical systems (MEMS) devices, configured to increase immunity of the pixel to molecular heat transfer and reduce the vacuum requirements for a wafer level packaged device incorporating the pixel or an array thereof. In one example, the pixel has a perforated body or discontinuous surface structure.

### CROSS REFERENCE TO RELATED APPLICATIONS

This application claims priority under 35 U.S.C. §119(e) to co-pending U.S. Provisional Application No. 61/660,068 filed Jun. 15, 2012 and titled “PIXEL STRUCTURE HAVING AN INTEGRAL ABSORBER WITH REDUCED VACUUM REQUIREMENTS,” which is hereby incorporated herein by reference in its entirety.

### BACKGROUND

Bolometers are thermal sensors that absorb infrared electromagnetic radiation, thereby increasing their temperature. The increase in temperature may be measured using any of various temperature sensing mechanisms, such as thermoelectric, pyroelectric or resistive temperature sensing principles for example, and used to produce a thermal image. Uncooled bolometer arrays are widely used for low-cost infrared imaging systems used in various applications, such as thermography, night vision, security and surveillance, for example.

A commonly used type of infrared imaging sensor is the focal plane array (FPA), which for thermal imaging includes infrared bolometer “pixels” arranged in a two-dimensional array. For many infrared imaging applications the bolometers are optimized to detect infrared radiation in the 8-14 micrometer (μm) wavelength region (referred to as long-wave infrared, or LWIR), and/or the 3-5 μm wavelength region (referred to as mid-wave infrared, or MWIR). The bolometers absorb incident electromagnetic radiation in the wavelength region of interest, which causes a thermally isolated bolometer membrane to increase in temperature. The temperature change correlates to the energy of the absorbed radiation and may be measured by measuring the change in electrical resistance of the bolometer thermistor material.

An important consideration in the design of uncooled infrared bolometer arrays is low thermal conductance between the bolometer and its surroundings to achieve high sensitivity for high performance imaging. Accordingly, the bolometer is typically suspended above a substrate containing the read-out electronics on long, thin “legs” having a small cross-sectional area and made of materials with low thermal conductivity. The legs generally include a metal layer to provide electrical connections between the bolometer and the read-out circuitry. In addition, bolometer arrays are often operated in a vacuum package to minimize thermal conduction between the bolometer and it packaging through surrounding gas. In conventional manufacturing of infrared bolometers, metal packaging, which may be hermetically sealed, may be used to achieve the vacuum chamber around the bolometer. In this type of packaging, relatively low vacuum pressure may be achieved and maintained. However, with wafer level packaging manufacturing, achieving a very low vacuum pressure is more difficult. In addition, sealed wafer level packaged bolometers suffer from low vacuum lifetime, at least in part due to outgassing from the substrate materials, which degrades the performance and reduces the lifetime of the sensor.

### SUMMARY OF THE INVENTION

Aspects and embodiments are directed to a pixel structure, which may be used for infrared bolometers or other microelectromechanical systems (MEMS) devices, that makes the pixel more immune to molecular heat transfer (thereby improving the thermal isolation of the device) and reduces the vacuum requirements for the packaged device.

According to one embodiment, a sealed wafer level packaged infrared imaging sensor comprises a vacuum packaged enclosure, and at least one infrared bolometer disposed within the vacuum packaged enclosure, the infrared bolometer configured to receive infrared electromagnetic radiation in a wavelength range of interest, and including a body having a plurality of holes extending therethrough, a size of each of the holes being less than a smallest wavelength in the wavelength range of interest.

In one example the sealed wafer level packaged infrared imaging sensor further comprises a substrate, and a cap wafer disposed over and attached to the substrate, the cap wafer and the substrate together providing the vacuum enclosure. The at least one infrared bolometer may include a plurality of infrared bolometers arranged in a two-dimensional array on the substrate and within the vacuum enclosure. The at least one infrared bolometer may further include at least one support attached to the body and coupled to the substrate and configured to support the body above the substrate. In one example the substrate includes read-out circuitry. In another example the at least one support includes a metal and provides an electrical connection between the body and the read-out circuitry. The wavelength range of interest may include a wavelength range from approximately 5 micrometers to approximately 14 micrometers, for example. In one example the size of each of the holes is less than or equal to approximately 1 micrometer. In another example the body includes a layer of vanadium oxide.

According to another embodiment a sealed wafer level packaged device comprises a vacuum packaged enclosure, and a MEMs device disposed within the vacuum packaged enclosure, the MEMs device having a discontinuous surface structure configured to limit molecular heat transfer between the MEMs device and the vacuum packaged enclosure.

In one example the MEMs device is a bolometer. In one example the bolometer has a body having a plurality of holes extending therethrough to provide the discontinuous surface structure. In another example the bolometer is configured to receive infrared electromagnetic radiation in a wavelength range of interest, and a size of each of the holes being less than a smallest wavelength in the wavelength range of interest. The wavelength range of interest may include a wavelength range from approximately 5 micrometers to approximately 14 micrometers, for example. The size of each of the holes is less than or equal to approximately 1 micrometer, for example.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a block diagram of a conventional bolometer pixel;

FIG. 2 is a block diagram of one example of a perforated pixel structure according to aspects of the invention;

FIG. 3 is a schematic diagram of one example of a vacuum-packaged bolometer pixel array according to aspects of the invention; and

FIG. 4 is a schematic top view of one example of a perforated pixel structure according to aspects of the invention.

### DETAILED DESCRIPTION

For many thermal imaging applications it is desirable that the thermal sensor be very sensitive to enable high resolution imaging. Good thermal isolation is generally essential to achieving a very sensitive infrared bolometer. The more thermally isolated the bolometer is, the more sensitive it is. In conventional bolometer arrays, some degree of thermal isolation is achieved through the use of very thin support legs with low thermal conductivity to support the bolometer material above the read-out circuitry substrate, as discussed above, and by placing the bolometer within a vacuum chamber. However, as also discussed above, in the context of wafer level packaged devices, achieving and maintaining low vacuum pressure is difficult. Outgassing of molecules from the materials within the vacuum chamber increases the pressure over time. For example, a device may have a vacuum pressure of approximately 0.5 millitorr at the time of manufacturing; however, molecular outgassing may increase this pressure on the order of about 5 times over the life of the device. Increased vacuum pressure causes increased molecular interactions, and therefore heat transfer, with the bolometer material, reducing the sensitivity and effectiveness of the sensor.

Some conventional approaches to addressing the problem of thermal isolation of infrared bolometers have included the incorporation of getter materials into the vacuum package space to absorb or trap outgassed molecules in order to reduce the vacuum pressure. Additionally, extensive efforts are undertaken to clean the surfaces of all of the components prior to vacuum sealing so as to reduce or eliminate outgassing sources. However, despite these efforts, the problem of an inability to achieve and maintain excellent thermal isolation with reasonable vacuum requirements for MEMS devices, including infrared bolometers, has persisted.

Aspects and embodiments are directed to a pixel structure that makes the pixel more immune to molecular heat transfer. In particular, aspects and embodiments are directed to a perforated bolometer or MEMs structure. Perforation in the pixel allows molecules to pass though some of the structure without thermal interaction, thus reducing the heat transfer and thereby maintaining the thermal isolation of the structure. A perforated pixel structure is able to tolerate a higher vacuum pressure than a non-perforated structure because there is less molecular thermal interaction and therefore greater thermal isolation. Thus, the perforated structure may increase the immunity of the device to vacuum pressure, thereby increasing the vacuum life and reliability of the device.

According to one embodiment, the problem of maintaining a very low vacuum pressure is addressed by effectively increasing the allowable vacuum pressure. In other words, the device is configured to tolerate a higher vacuum pressure with little or no degradation in performance. According to one embodiment, perforation in the pixel allows molecules to pass though some of the structure without thermal interaction, thus reducing the heat transfer and thereby maintaining the thermal isolation of the structure.

Referring to FIG. 1, there is illustrated a schematic diagram of a conventional MEMS pixel structure. In this example, the MEMS device 110 has a continuous surface structure, as illustrated. As a result, molecules 120 interact with the MEMs structure 110 and do not travel uninterrupted from enclosure wall 130 to enclosure wall 130. Each molecular interaction between a molecule 120 and the MEMS device 110 may cause heat transfer from the molecule to the MEMS device, which reduces the thermal isolation of the device.

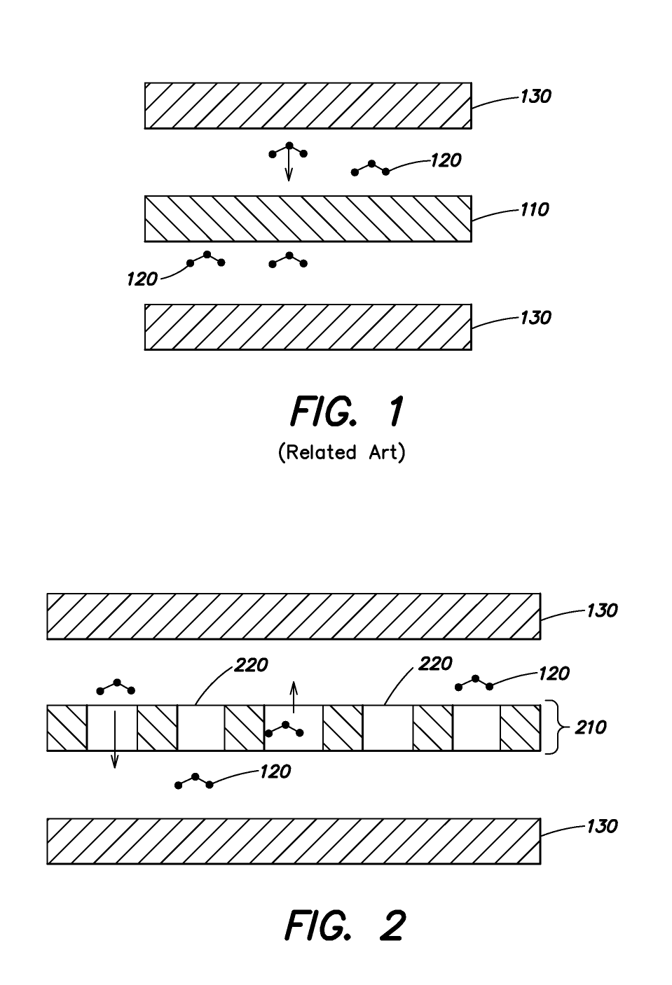

In contrast, embodiments of a pixel according to aspects of the invention have a perforated structure, an example of which is shown schematically in FIG. 2, to reduce the exposed surface area of the pixel for interaction with molecules 120. As shown in FIG. 2, the pixel includes a body 210 that has a perforated or discontinuous surface structure with holes 220 that extend through the body. As the molecules 120 collide back and forth from the enclosure walls 130 to the pixel to the enclosure walls, they transfer heat to the pixel which reduces the sensitivity of the pixel. However, with a perforated pixel body structure 210, some of the molecules 120 will go through the pixel (through the holes 220 in the body) without interacting with the pixel. Thus, in the case of a bolometer, at least some of the molecules 120 may pass through the pixel without exchanging heat with the bolometer material (e.g., without transferring heat from the enclosure walls 130 to the bolometer material). The perforated body 210 decreases the pixel area available for thermal interaction. This improves the pixel thermal isolation and increases the immunity of the device to vacuum pressure, and may provide for greater lifetime and the ability to increase the package vacuum pressure while maintaining reasonable thermal isolation.

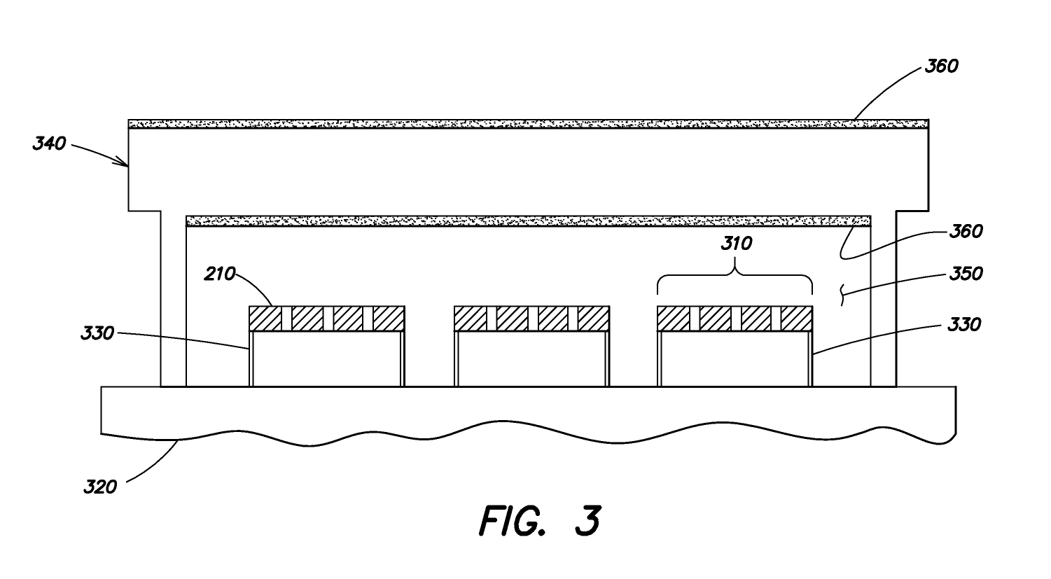

According to one embodiment, numerous perforated bolometer pixels may be included in wafer level packaged array, an example of which is illustrated schematically in FIG. 3. The pixels 310 may be arranged in a one-dimensional or two-dimensional array on a substrate 320. Each pixel 310 includes a perforated body 210, as discussed above, and supports or legs 330 that suspend the body above the substrate 320. In one example, length of the pixel body 210 is approximately 17 μm, and each leg 330 has a diameter of approximately 1 μm. As discussed above, the legs 330 may be metal or may include a metal layer to provide electrical connections between the pixel 310 and circuitry included on or within the substrate 320. Those skilled in the art will appreciate, given the benefit of this disclosure, that the substrate 320 may include various layers, structures, interconnections etc. (not shown) to provide an operating bolometer array. A cap wafer 340 is positioned over the pixels 310 and attached to the substrate 320 to provide a vacuum enclosure 350 around the pixels. The cap wafer 340 may include one or more coatings 360 which may be anti-reflective or other coatings, as will be appreciated by those skilled in the art, given the benefit of this disclosure. In one example the cap wafer 340 is a silicon wafer.

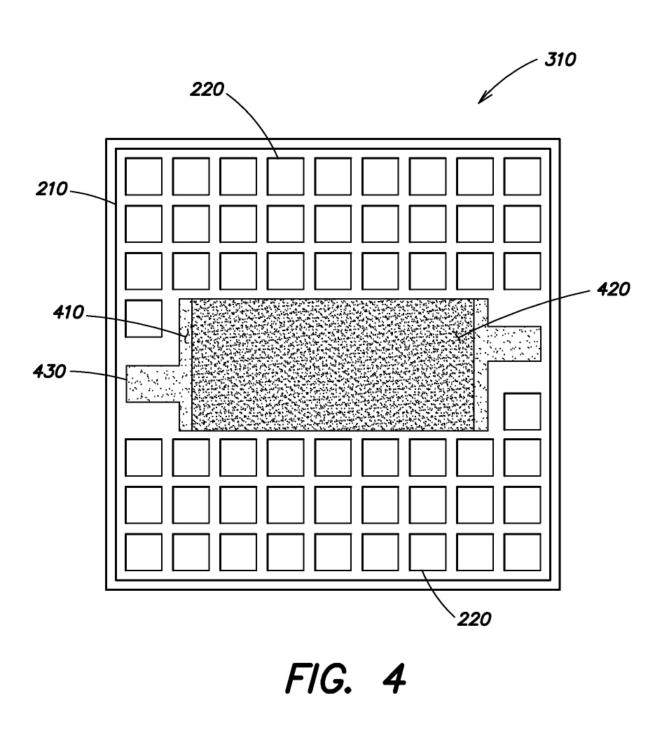

FIG. 4 is a top view of one example of a perforated pixel structure according to one embodiment. In the illustrated example, the majority of the pixel body 210 is perforated with an array of holes 220. Although the holes 220 are illustrated as square in FIG. 4, the holes may have any shape and are not limited to being square. The pixel 310 further includes a layer of bolometer material 410 partially covered by an infrared absorber layer 420. The absorber layer 420 may improve the infrared collection capability of the pixel 310. In one example the bolometer material 410 is vanadium oxide; however, various other temperature sensing materials may be used, such as but not limited to amorphous silicon, silicon diodes, thin film metals, amorphous germanium-silicon-oxygen compounds, or poly-crystalline silicon-germanium, for example. The layer of bolometer material 410 may include tabs 430 for electrical connection to the legs 330 or other structure that electrically connect the pixel 310 to associated read-out circuitry.

In one example, the pixel 310 has approximately a 45% reduction in cross-sectional area, due to the holes 220, relative to a conventional non-perforated structure of similar dimensions. Thus, the available area for molecular interactions is greatly reduced, such that the pixel 310 has a reduced accommodation coefficient (ability to molecularly transfer heat), thereby improving the thermal isolation of the pixel. In one embodiment, the size of holes 220 is selected to be small compared to the wavelengths of electromagnetic radiation that the pixel 310 is designed to be responsive to. In addition, the size of the holes 220 may be sufficiently large to allow gas molecules to pass freely through. Thus, from the molecular point of view, the holes 220 are large and the molecules pass through the pixel with little or no thermal interactions; however, from the wavelength perspective the pixel body 210 appears solid, such that the thermal collection capability of the pixel is substantially unaffected by the perforations. For example, for an infrared bolometer designed for wavelengths in the range of approximately 5 to 14 μm, the holes may have a diameter or side length (depending on shape) of approximately 1 μm. Selecting the hole size to be less than approximately a quarter-wavelength at the smallest wavelength of interest may ensure that the pixel surface appears substantially solid to the wavelength range of interest.

Thus, according to aspects and embodiments, a MEMS structure, such as a bolometer for example, having a discontinuous surface designed to limit molecular heat transfer with its surroundings is provided. In certain examples, the discontinuous surface design reduces the view factor from the vacuum package walls to the MEMs structure. As a result, thermal isolation of the MEMS structure may be improved, which may improve the performance (sensitivity) of the sensor and/or reduce the vacuum requirements of the package since a higher vacuum pressure may be tolerated with little to no degradation in performance.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only. It is to be appreciated that embodiments of the structures discussed herein are not limited in application to the details of construction and the arrangement of components set forth in the description or illustrated in the accompanying drawings. Aspects and embodiments are capable of implementation in other forms and of being practiced or of being carried out in various ways. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. The scope of the invention should be determined from proper construction of the appended claims, and their equivalents.

What is claimed is:

1. A sealed wafer level packaged infrared imaging sensor comprising:
a vacuum packaged enclosure; and
at least one infrared bolometer disposed within the vacuum packaged enclosure, the infrared bolometer configured to receive infrared electromagnetic radiation in a wavelength range of interest, and including a body having a plurality of holes extending therethrough, a size of each of the holes being less than a smallest wavelength in the wavelength range of interest.

2. The sealed wafer level packaged infrared imaging sensor of claim 1, further comprising:
a substrate; and
a cap wafer disposed over and attached to the substrate, the cap wafer and the substrate together providing the vacuum enclosure.

3. The sealed wafer level packaged infrared imaging sensor of claim 2, wherein the at least one infrared bolometer includes a plurality of infrared bolometers arranged in a two-dimensional array on the substrate and within the vacuum enclosure.

4. The sealed wafer level packaged infrared imaging sensor of claim 2, wherein the at least one infrared bolometer further includes at least one support attached to the body and coupled to the substrate and configured to support the body above the substrate.

5. The sealed wafer level packaged infrared imaging sensor of claim 4, wherein the substrate includes read-out circuitry.

6. The sealed wafer level packaged infrared imaging sensor of claim 5, wherein the at least one support includes a metal and provides an electrical connection between the body and the read-out circuitry.

7. The sealed wafer level packaged infrared imaging sensor of claim 1, wherein the wavelength range of interest includes a wavelength range from approximately 5 micrometers to approximately 14 micrometers.

8. The sealed wafer level packaged infrared imaging sensor of claim 7, wherein the size of each of the holes is less than or equal to approximately 1 micrometer.

9. The sealed wafer level packaged infrared imaging sensor of claim 1, wherein the body includes a layer of vanadium oxide.

10. A sealed wafer level packaged device comprising:
a vacuum packaged enclosure; and
a MEMs device disposed within the vacuum packaged enclosure, the MEMs device having a discontinuous surface structure configured to limit molecular heat transfer between the MEMs device and the vacuum packaged enclosure.

11. The sealed wafer level packaged device of claim 10, wherein the MEMs device is a bolometer.

12. The sealed wafer level packaged device of claim 11, wherein bolometer has a body having a plurality of holes extending therethrough to provide the discontinuous surface structure.

13. The sealed wafer level packaged device of claim 12, wherein the bolometer is configured to receive infrared electromagnetic radiation in a wavelength range of interest, and a size of each of the holes being less than a smallest wavelength in the wavelength range of interest.

14. The sealed wafer level packaged device of claim 13, wherein the wavelength range of interest includes a wavelength range from approximately 5 micrometers to approximately 14 micrometers.

15. The sealed wafer level packaged device of claim 14, wherein the size of each of the holes is less than or equal to approximately 1 micrometer.
